(19) United States
(12) Patent Application Publication
(10) Pub. No.: US 2009/0041925 A1
(43) Pub. Date: Feb. 12, 2009

(54) System and Method for Endpoint Detection of a Process in a Chamber

(75) Inventors: Christopher William Lewis, Austin, TX (US); Alan Lee Atherton, Austin, TX (US)

Correspondence Address: DUBOIS, BRYANT, CAMPBELL & SCHWARTZ, LLP, 700 LAVACA STREET, SUITE 1300, AUSTIN, TX, 78701, US

(73) Assignee: ADVANCED REFURBISHMENT TECHNOLOGIES LLC, Austin, TX (US)

(21) Appl. No.: 12/139,149

(22) Filed: Jun. 13, 2008

Related U.S. Application Data
(60) Provisional application No. 60/943,702, filed on Jun. 13, 2007.

(51) Int. Cl. C23C 16/52; B05C 11/00

(52) U.S. Cl. 427/8; 118/699; 118/697

(57) ABSTRACT

A system and method which implements a preferred embodiment of the present invention detects the endpoint of a process by monitoring changes in chamber pressure in real time. The endpoint of a process may be detected for processes that produce measurable changes in chamber pressure. For example, chemical reactions conducted within the chamber, such as during a cleaning process, may result in changes to chamber pressure. As the chamber is cleaned, the chamber pressure is maintained using an evacuation conductance modulating device, such as a throttle valve, to prevent gaseous by-products of the cleaning process from changing the chamber pressure. As the cleaning process progresses, less contaminants exist and less by-product evolves. As a result, if the throttle valve position is held constant, then variables, such as a decrease in the rate of change in chamber pressure, can be used to detect the endpoint of the process.

### CROSS-REFERENCE TO RELATED APPLICATIONS

This non-provisional application claims priority based upon prior U.S. Provisional Patent Application Ser. No. 60/943702 filed Jun. 13, 2007 in the name of Christopher William Lewis and Alan Lee Atherton, entitled “Method for Endpoint of Clean Detection for Chemical Vapor Deposition Chamber Using Manometer,” the disclosure of which is incorporated herein by reference.

### FIELD OF THE INVENTION

The present invention relates generally to semiconductor processing and, more particularly, to a method for determining the endpoint of a process performed within a processing chamber.

### BACKGROUND OF THE INVENTION

In the fabrication of semiconductor devices, etching and deposition processes are performed in a specific sequence on a substrate utilizing processing chambers to form the integrated circuit structures. Processes such as chemical vapor deposition (CVD), etching, and others are performed in processing chambers. With each process being performed on the substrate there is an incremental residual build up in the processing chamber. For example, during CVD, TEOS (Tetra Ethyl Ortho Sillicate) materials are deposited on surfaces of the CVD deposition chamber which are exposed to the process, as well as on the substrate. In other words, each wafer receives a specific amount of deposition and the exposed area of the chamber receives a proportional amount of material. This material must be removed from the exposed portions of the chamber before the material achieves a thickness that allows the material to flake or peel off the surface of the chamber. Any such flaking or peeling off of material increases the number and rate of defects in the integrated circuit structures and results in a loss of performance for the integrated circuits.

To remove this deposited material from the chamber, deposition chambers are cleaned at specific frequencies, such as after every wafer processing or as much as after every 10^{th} wafer processing, depending upon the amount of deposition per substrate that has occurred and the propensity that the material has to commence flaking from the walls. Such cleaning often utilizes a plasma and chemical compounds which react with the deposited material to form a compound which is then pumped from the chamber. Use of a plasma may also result in physical bombardment of the etching species to dislodge the material from the chamber surfaces.

During the cleaning of the chamber, no deposition or etching of a semiconductor substrate may be performed. In order to maximize the productivity of a chamber, it is desirable to increase the ratio of chamber deposition time relative to cleaning time but not at the cost of increasing the number of defects caused by material flaking. Existing chambers, however, do not have a means to economically determine the endpoint of the chamber cleaning process, and, as a result, the cleaning time is extended well beyond a point where residual material is being removed in order to reduce the potential risk of material flaking. Consequently, existing chambers fail to maximize the ratio of chamber deposition time to cleaning time, causing a loss in chamber productivity. Moreover, existing solutions in the art, such as that of U.S. Pat. No. 6,358,327B1, are not economically viable for many existing deposition chambers, particularly if a retrofit of the deposition chamber would be required to implement the solution.

In order to economically determine the endpoint, and increase the ratio of in chamber production time versus cleaning time, there is a considerable need for a system and method which will economically and accurately determine the endpoint of a chamber cleaning process. Further, it can be valued that the system and method which are the subjects of this invention minimize cleaning operation time, which leads to that time being utilized for highly valuable chamber production time. The present invention provides these and other advantages, as will be apparent from the following detailed description and accompanying figures.

### BRIEF SUMMARY OF THE INVENTION

A system and method which implements a preferred embodiment of the present invention detects the endpoint of a process by monitoring changes in chamber pressure in real time. The endpoint of a process may be detected for processes that produce measurable changes in chamber pressure. For example, chemical reactions conducted within the chamber, such as during a cleaning process, may result in changes to chamber pressure. As the chamber is cleaned, the chamber pressure is maintained using an evacuation conductance modulating device, such as a throttle valve, to prevent gaseous by-products of the cleaning process from changing the chamber pressure. As the cleaning process progresses, less contaminants exist and less by-product evolves. As a result, if the throttle valve position is held constant, then variables, such as a decrease in the rate of change in chamber pressure, can be used to detect the endpoint of the process.

Deposition, cleaning and etching processes often have unique combinations of substantially constant input conditions (e.g., reactant gas flow, chamber volume, chamber temperature, pumping speed, pumping conductance) and, at the same time, have unique patterns of chamber pressure fluctuations over the course of such processes. Accordingly, monitoring the chamber pressure fluctuation data while such processes are performed allows for the detection of the endpoint of such processes. For example, the endpoint of a production process may be estimated by real time analysis of chamber pressure data (including raw data, numerically or algorithmically filtered data) to ascertain the presence, or absence, of any number of sequential specific data trend features. Such features may include, but are not limited to, the magnitude and sign of the rate of pressure change (positive to indicate an increasing pressure or negative for decreasing pressure), and the duration of such pressure change.

### BRIEF DESCRIPTION OF THE DRAWINGS

FIG. 1 is a simplified illustration of the substantially top perspective view of a chamber that includes components to implement a preferred embodiment of the present invention;

FIG. 2 is a simplified illustration of a cross-sectional schematic view of a chamber that includes components to implement a preferred embodiment of the present invention;

FIG. 3 is a simplified partial bottom perspective view of a chamber that includes components to implement a preferred embodiment of the present invention; and

FIG. 4 is a flowchart illustrating the operation of significant functions in a preferred embodiment of the present invention.

### DETAILED DESCRIPTION

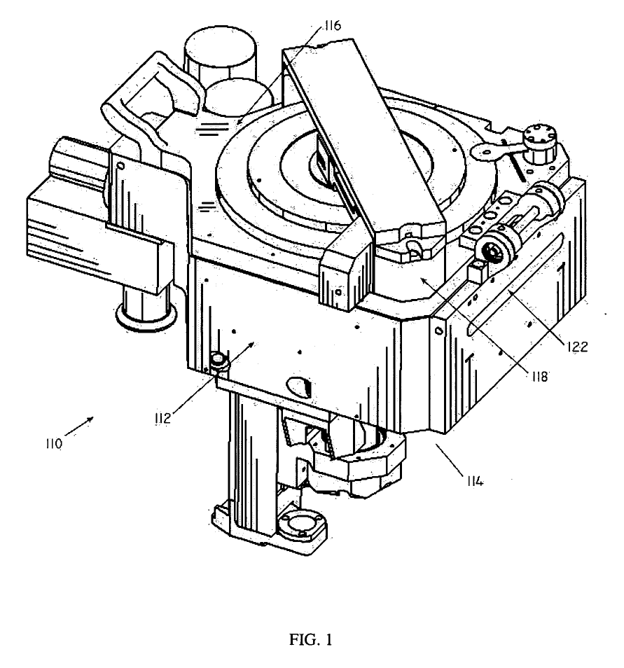

Reference is now made to FIG. 1 which is a simplified illustration of the substantially top perspective view of a chamber that includes components to implement a preferred embodiment of the present invention. The chamber 110, also commonly referred to as a deposition chamber or processing chamber, includes a sidewall 112 and a lid 116. A slit valve 122, shown on the sidewall 112, allows substrates or wafers to travel in and out of the chamber 110. The lid 116 forms a vacuum seal when closed. In this embodiment, process gases may flow through the lid 116 into the chamber 110. The chamber 110 may also include a pressure control system for adjusting pressure within the chamber 110. In this embodiment, a gas distribution system 118 is used to control the flow and delivery of process gases into the chamber 110. In one embodiment, a separate gas supply is connected to the gas distribution system 118 for processing and a separate gas supply is connected to the gas distribution system 118 for cleaning. One example of a commercially available chamber which can benefit from the advantages of the present invention is the DxZ Chamber, available from Applied Materials, Inc.

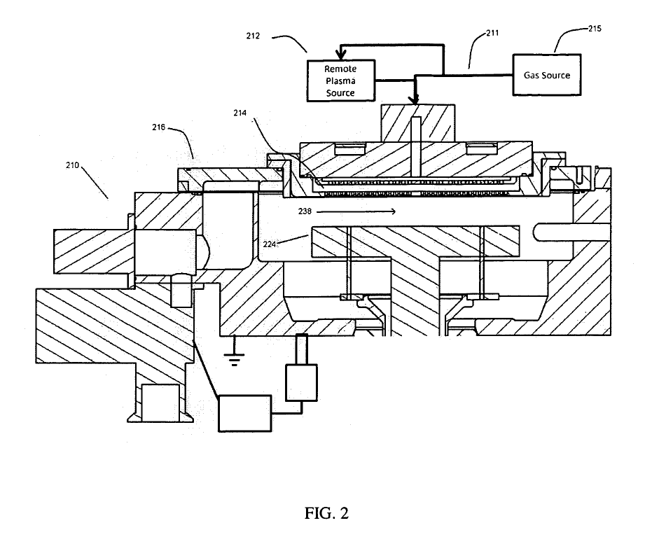

Reference is now made to FIG. 2 which is a simplified illustration of a cross-sectional schematic view of a chamber that includes components to implement a preferred embodiment of the present invention. A substrate may be positioned on a substrate support 224 directly below a gas distributor 214. The gas distributor 214 is located below the central portion of the lid 216. In one embodiment, a cleaning process in the chamber 210 is initiated by the transportation of the substrate 222 out of the chamber 210.

A gas source 215 and a remote plasma generator 212 are shown connected together via a gas line 211. The remote plasma generator 212 generates a plasma which can be delivered with process gasses to the process zone 238 of the chamber 210. Although not shown, the gas line 211 is also connected to the gas distribution system 118 shown in FIG. 1. The process gases and plasma, after passing through the gas distribution system 118, pass through the gas distributor 214 upon entering the chamber 210. In the chamber 210, the reactive gas radicals, created by the plasma reactions with the process gasses, vaporize contaminants and production byproducts in the chamber 210.

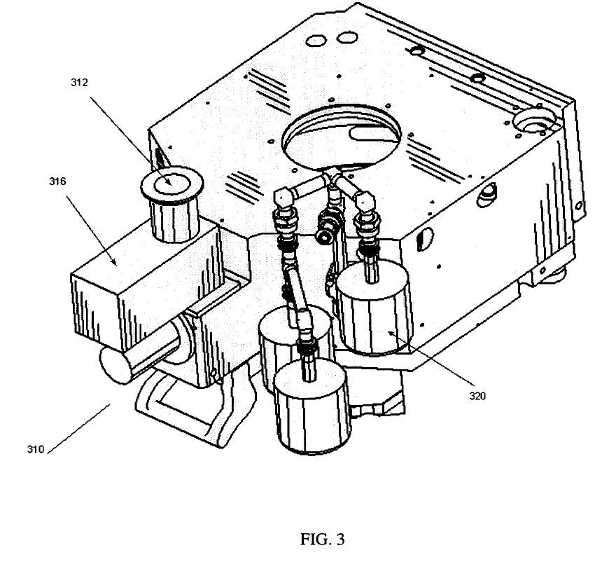

Reference is now made to FIG. 3 which is a simplified partial bottom perspective view of a chamber that includes components to implement a preferred embodiment of the present invention. In this embodiment, a throttle valve 316 and an instrument 320 for monitoring chamber pressure are shown as components of a pressure control system. The pressure control system also contains an exhaust passage 312 to enable monitoring and adjusting of the pressure within the chamber 310 for various processing needs. The instrument 320 for monitoring pressure may consist of a capacitance manometer, thermo-couple, ion gauge, or other similar instrument known in the art.

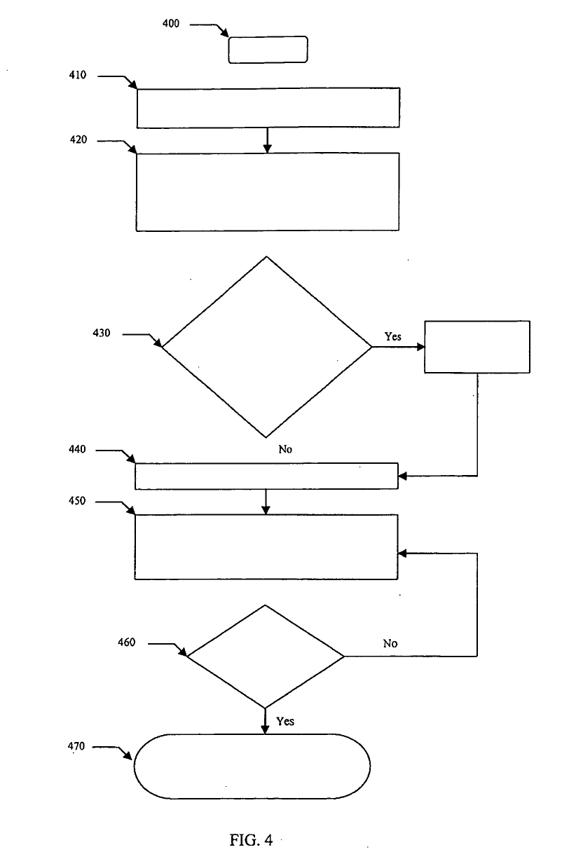

Reference is now made to FIG. 4 which is a flowchart illustrating the operation of significant functions in a preferred embodiment of the present invention. As well, references to components shown in FIGS. 1, 2, & 3 continue to be used hereinafter. At a start 400, it is assumed in this example embodiment that the production process has been completed. In step 410, process gases are introduced to the chamber 110 via the gas distribution system 118 at a substantially constant flow rate and/or substantially constant pumping speed. In step 420, a specific chamber pressure is established and maintained with the pressure control system. Chamber pressure can be maintained by adjusting the position of the throttle valve 316 in response to a chamber pressure reading from the instrument 320 for monitoring chamber pressure.

In choice 430, if the desired cleaning process involves a form of excitation, such as by a form of radio frequency or light, for the purpose of chemical activation, the excitation source is started and the system proceeds to step 440. For example, starting the excitation source may consist of powering a remote plasma generator 212. The remote plasma generator 212 activates chemicals in the chamber 210 which begin to vaporize the contaminants in the chamber 210. This vaporization of contaminants cleans the chamber 210. At the same time, the vaporization serves to increase the amount of gas in the chamber 210 and raise the pressure in the chamber 210. If excitation is not necessary, the system can proceed directly to step 440.

In step 440, the position of the throttle valve 316 is locked at its current position and the chamber pressure is allowed to fluctuate. In one embodiment, the position of the throttle valve 316 is not locked until after a set period of time has passed, such as 5 to 10 seconds, from the time that vaporization has been initiated.

In step 450, the system monitors the pressure in the chamber 210 as the cleaning process proceeds. The amount of contaminants in the chamber 210 decreases as the cleaning process progresses and, as a result, the rate of vaporization of such contaminants eventually decreases and pressure fluctuations in the chamber 210 decrease. In choice 460, the system determines whether the fluctuations in the pressure of the chamber 210 have decreased to a level that equals or exceeds the endpoint criteria. If the endpoint criteria have been satisfied, then the cleaning process is determined to be complete and the system begins to initiate the next production process. If the endpoint criteria have not been satisfied, then the system returns to step 450. In one embodiment, the endpoint criteria are satisfied after (i) a predefined minimum time has elapsed; (ii) then, an observable increase or decrease in pressure greater than some established rate has been observed; and (iii), then, a period of pressure change less than some established rate has been observed. In some embodiments, it may be desirable to continue production processing for a short period of time beyond the determined endpoint time to ensure that the process is complete.

An exemplary cleaning operation wherein silicon dioxide is cleaned from the surfaces of a chamber is now described. To clean silicon dioxide from the surfaces of the chamber, a process gas for cleaning, such as a 2:1 mixture of argon (Ar) and nitrogen trifluoride (NF₃), is first supplied to the chamber through the gas distribution system at a selected constant flow rate. In one embodiment the constant flow rate is selected from a range of between about 1000 standard cubic centimeters per minute and about 3000 standard cubic centimeters per minute. In another embodiment the constant flow rate is selected at about 2100 standard cubic centimeters per minute. The remote plasma generator then generates plasma from the process gas for cleaning to create fluorine and nitrogen radicals that are supplied to the chamber. In one embodiment, this exemplary silicon dioxide cleaning process is most efficient at a chamber pressure of about 4 Torr. Accordingly, the chamber pressure is maintained at about 4 Torr for the first 5 to 10 seconds of the cleaning process. The chamber pressure is then allowed to change in response to the evolution of gaseous by-products as the cleaning process continues.

Silicon dioxide deposited on the interior chamber surfaces, and on other components within the processing chamber, reacts with fluorine (F) radicals generated in the NF₃ plasma to form a gas known as silicon tetrafluoride (SiF₄). Because silicon tetrafluoride formation is exothermic, heat is generated during chamber cleaning. If the pumping rate of the pressure control system is not increased accordingly, (e.g., the throttle valve is locked in position) the increased temperature will cause a slight increase in the pressure within the chamber. The reaction between silicon dioxide and fluorine continues until all of the residual silicon dioxide reacts with fluorine, and the cleaning operation is complete. As the cleaning operation nears completion, and the formation of silicon tetrafluoride gradually decreases and the chamber pressure returns to the initially desired maintenance pressure, in this example about 4 Torr.

A computer program may be used to implement significant functions of a preferred embodiment of the present invention, such as performing a digital signal processing to determine and detect the endpoint of the cleaning process. More specifically, a computer program may analyze a time varying raw or filtered signal collected from an instrument monitoring the chamber pressure. For example, a computer program may be used to (i) analyze specific features or trends related to the predictable increase or decrease in chamber pressure; (ii) filter time varying signals by, for example, time averaging, numerically averaging, or algorithmically altering filtering; (iii) analyze rate of change in pressure (dP) with time (dt) expressed as a slope (dP/dt); (iv) identify positively (+) signed values indicating increasing pressure over time and negatively (−) signed values indicating decreasing pressure over time; and (v) analyze sequential combinations of slopes, slopes greater than, equal to, or less than pre-determine limits, and slopes persisting for more or less than pre-determined times intervals. The computer program can also have (a) a means for storing a set of pressure data feature descriptions for comparison to pressure data actively gathered from pressure sensing instrumentation and (b) a means for directing a controller to end a production instance of the process based on the determined endpoint condition.

It is appreciated that various features of the invention which are, for clarity, described in the context of separate embodiments may also be provided in combination in a single embodiment. Conversely, various features of the invention which are, for brevity, described in the context of a single embodiment may also be provided separately or in any suitable combination.

It will be appreciated by persons skilled in the art that the present invention is not limited by what has been particularly shown and described hereinabove and other embodiments may fall within the spirit and scope of the invention, as defined by the following claims.

What is claimed is:

1. A method for detecting the endpoint of a process comprising:
(a) introducing, at a substantially constant flow rate, at least one process gas into a chamber;
(b) maintaining a substantially constant pressure within said chamber;
(c) locking an evacuation conductance modulating device so that said chamber pressure is allowed to fluctuate;
(d) monitoring said chamber pressure;
(e) comparing results from said monitoring to at least one predetermined endpoint criterion; and
(f) repeating steps (d) and (e) above until said results from said monitoring satisfy said at least one predetermined endpoint criterion.

2. The method of claim 1 wherein said maintaining a substantially constant pressure within said chamber involves adjusting said evacuation conductance modulating device.

3. The method of claim 1 further comprising initiating an excitation source after step (b) above.

4. The method of claim 3 wherein said locking occurs a predetermined period of time after said initiating.

5. The method of claim 3 wherein said excitation source is a remote plasma generator.

6. The method of claim 3 wherein said excitation source chemically activates said at least one process gas.

7. The method of claim 6 wherein said chemically activated at least one process gas serves to vaporize contaminants in said chamber.

8. The method of claim 7 wherein said contaminants include silicon dioxide.

9. The method of claim 1 wherein said at least one predetermined endpoint criterion includes the passing of a predetermined amount of time, an increase or decrease in said chamber pressure greater than a predetermined rate, and a period of change of said chamber pressure less than a predetermined rate.

10. The method of claim 1 wherein said at least one process gas contains a mixture of argon and nitrogen trifluoride.

11. The method of claim 1 wherein said substantially constant flow rate is in the range of about 1000 standard cubic centimeters per minute and about 3000 standard cubic centimeters per minute.

12. The method of claim 1 wherein said substantially constant flow rate is about 2100 standard cubic centimeters per minute.

13. The method of claim 1 wherein said substantially constant pressure is about 4 Torr.

14. The method of claim 1 wherein said monitoring includes using a computer program to analyze a time varying raw or filtered signal representative of said chamber pressure.

15. The method of claim 1 further comprising storing said results from said monitoring for the purpose of developing future endpoint criteria.

16. The method of claim 1 further comprising directing a controller to end said process after said results from said monitoring satisfy said at least one predetermined endpoint criterion.

17. A system for detecting the endpoint of a process comprising:
a chamber wherein at least one process gas is introduced at a substantially constant flow rate into said chamber and the pressure within said chamber is maintained at a substantially constant pressure;
an evacuation conductance modulating device wherein, after said pressure within said chamber has been maintained at a substantially constant pressure for a predetermined amount of time, said evacuation conductance modulating device is locked so that said chamber pressure is allowed to fluctuate; and
wherein said chamber pressure is monitored, and the results of said monitoring are compared to at least one predetermined endpoint criterion, until said results from said monitoring satisfy said at least one predetermined endpoint criterion.

18. The system of claim 17 wherein said maintenance of said chamber pressure at a substantially constant pressure is performed by said evacuation conductance modulating device.

19. The system of claim 17 further comprising an excitation source.

20. The system of claim 19 wherein said evacuation conductance modulating device is locked a predetermined period of time after said excitation source is initiated.

21. The system of claim 19 wherein said excitation source is a remote plasma generator.

22. The method of claim 19 wherein said excitation source chemically activates said at least one process gas.

23. The system of claim 22 wherein said chemically activated at least one process gas serves to vaporize contaminants in said chamber.

24. The system of claim 23 wherein said contaminants include silicon dioxide.

25. The system of claim 17 wherein said at least one predetermined endpoint criterion includes the passing of a predetermined amount of time, an increase or decrease in said chamber pressure greater than a predetermined rate, and a period of change of said chamber pressure less than a predetermined rate.

26. The system of claim 17 wherein said at least one process gas contains a mixture of argon and nitrogen trifluoride.

27. The system of claim 17 wherein said substantially constant flow rate is in the range of about 1000 standard cubic centimeters per minute and about 3000 standard cubic centimeters per minute.

28. The system of claim 17 wherein said substantially constant flow rate is about 2100 standard cubic centimeters per minute.

29. The system of claim 17 wherein said substantially constant pressure is about 4 Torr.

30. The system of claim 17 further comprising processor instructions stored on a computer usable medium for causing a computer to perform said monitoring and comparing and wherein at least one of said monitoring or comparing includes analyzing a time varying raw or filtered signal representative of said chamber pressure.

31. The system of claim 17 wherein said results from said monitoring are stored for the purpose of developing future endpoint criteria.

32. The system of claim 17 further comprising a controller wherein said controller signals the end of said process after said results from said monitoring satisfy said at least one predetermined endpoint criterion.
